(19) United States
(12) Patent Application Publication
(10) Pub. No.: US 2026/0247835 A1
(43) Pub. Date: Aug. 20, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-si (KR)

(72) Inventors: Chang Han LEE, Yongin-si (KR); Hyo Jin KIM, Yongin-si (KR); Hyang Yul KIM, Yongin-si (KR); Su Hyun OH, Yongin-si (KR); Deok Hyeon JANG, Yongin-si (KR)

(21) Appl. No.: 19/414,054

(22) Filed: Dec. 9, 2025

(30) Foreign Application Priority Data
Feb. 14, 2025 (KR) 10-2025-0019293

(51) Int. Cl. H10K 59/80; H10K 59/12; H10K 59/131; H10K 71/70

(52) U.S. Cl. CPC H10K 59/8722; H10K 59/1201; H10K 59/131; H10K 71/70

(57) ABSTRACT

A method of manufacturing a display device includes: forming a plurality of cell units including an display element and a pad on a base substrate; forming a damping stack on the base substrate, wherein the damping stack comprises a substrate layer covering the cell units and having a transmittance of 20% or less for a light having a wavelength of 380 nanometers (nm) or less, and an adhesive layer formed on one surface of the substrate layer; removing a portion of the damping stack covering the pad; and curing a remaining portion of the damping stack using a light having a wavelength of 390 nm or more.

### CROSS-REFERENCE TO RELATED APPLICATION

The present application claims priority to and the benefit of Korean Patent Application No. 10-2025-0019293, filed on Feb. 14, 2025, in the Korean Intellectual Property Office, the entire disclosure of which is incorporated herein by reference.

### BACKGROUND

### 1. Field

Aspects of some embodiments of the present disclosure relate to a display device, a method of manufacturing the same and an electronic device including the same.

### 2. Description of the Related Art

In a display device such as an organic light emitting diode (OLED) display device and a liquid crystal display (LCD) device, a display substrate including a thin film transistor (TFT) and various types of wirings may be included, and a display structure including wirings pads, and a light-emitting element may be formed on the display substrate.

Unit cells including the display structure may be formed on the substrate, and then a protective film (a release film) may be attached to the unit cells. After the unit cells are cut, the protective film may be removed. Thereafter, additional functional layers may be bonded to upper and lower portions of the unit cell.

The above information disclosed in this Background section is only for enhancement of understanding of the background and therefore the information discussed in this Background section does not necessarily constitute prior art.

### SUMMARY

Aspects of some embodiments of the present disclosure relate to a display device, a method of manufacturing the same and an electronic device including the same. For example, aspects of some embodiments of the present disclosure relate to a display device including a display element and a protective layer, a method of manufacturing the same and an electronic device including the same.

Aspects of some embodiments of the present disclosure include a display device having relatively improved mechanical properties and process reliability.

Aspects of some embodiments of the present disclosure include a method of manufacturing a display device having relatively improved mechanical properties and process reliability.

Aspects of some embodiments of the present disclosure include an electronic device including a display device with relatively improved mechanical properties and process reliability.

According to some embodiments of the present disclosure in a method of manufacturing a display device, a plurality of cell units including an display element and a pad may be formed on a base substrate. According to some embodiments, a damping stack may be formed on the base substrate. According to some embodiments, the damping stack may include a substrate layer covering the cell units and having a transmittance of 20% or less for a light having a wavelength of 380 nm or less, and an adhesive layer formed on one surface of the substrate layer. According to some embodiments, a portion of the damping stack covering the pad may be removed. According to some embodiments a remaining portion of the damping stack may be cured using a light having a wavelength of 390 nm or more.

According to some embodiments, after forming the damping stack. a full-cutting for an individual separation of the cell units may be performed. According to some embodiments, a partial-cutting for partially cutting only the damping stack may be performed.

According to some embodiments, the full-cutting may be performed along a first cutting line extending along a periphery of the cell unit, and the partial-cutting may be performed along a second cutting line defining a pad area in which the pad is arranged.

According to some embodiments, in the removal of the portion of the damping stack covering the pad, a portion of the damping stack formed on the pad area may be peeled.

According to some embodiments, a lighting test may be performed through the pad after removing the damping stack or curing the damping stack.

According to some embodiments, the pad may be removed by at least partially cutting the pad area after performing the lighting test.

According to some embodiments, the transmittance of the substrate layer for the light having a wavelength of 380 nm or less may be 10% or less.

According to some embodiments, a transmittance of the substrate layer for the light having a wavelength of 390 nm or more may be 20% or more.

According to some embodiments, a transmittance of the substrate layer for a light having a wavelength of 400 nm or more may be 50% or more.

According to some embodiments, an adhesive force of the adhesive layer before curing may be 70 grams-force per inch (gf/in) or less.

According to some embodiments, an adhesive force of the adhesive layer after curing may be 250 grams-force per inch (gf/in) or more.

According to some embodiments, the adhesive force of the adhesive layer after curing may be 300 grams-force per inch (gf/in) or more.

According to some embodiments, the damping stack may further include a protective layer formed on the other surface of the substrate layer, and an adhesive force of the protective layer to the substrate layer before curing may be greater than an adhesive force of the substrate layer to the adhesive layer before curing.

According to some embodiments, transmittance of the substrate layer for a light having a wavelength in a range from 9 μm to 11 μm may be 10% or less.

According to some embodiments of the present disclosure, a display device may include a base substrate, a transistor on the base substrate, a light-emitting element electrically connected to the transistor, and a damping stack covering the light-emitting element. According to some embodiments, the damping stack may include a substrate layer having a transmittance of 20% or less for a light having a wavelength of 380 nm or less and a transmittance of 20% or more for a light having a wavelength of 390 nm or more, and an adhesive layer on one surface of the substrate layer.

According to some embodiments, a transmittance of the substrate layer for the light having a wavelength of 380 nm or less may be 10% or less, and a transmittance of the substrate layer for the light having a wavelength of 390 nm or more may be 30% or more.

According to some embodiments, an end portion of the damping stack may have an inclined surface having an inclination angle of 50° to 80° with respect to a top surface of the base substrate.

According to some embodiments, the base substrate may have a display area in which the transistor and the light-emitting element are arranged and a margin area around the display area. According to some embodiments, the damping stack may include a tail portion extending from the end portion to the margin area.

According to some embodiments, the damping stack may include a protrusion formed on an upper portion of the end portion, and a height of the protrusion may be in a range from 5 μm to 30 μm from a top surface of the damping stack.

According to some embodiments of the present disclosure, an electronic device may include a display device, a memory, and a processor configured to control an operation of the display device by executing data included in the memory. According to some embodiments, the display device may include a base substrate, a transistor on the base substrate, a light-emitting element electrically connected to the transistor, and a damping stack covering the light-emitting element. According to some embodiments, the damping stack may include a substrate layer having a transmittance of 20% or less for a light having a wavelength of 380 nm or less and a transmittance of 20% or more for a light having a wavelength of 390 nm or more, and an adhesive layer on one surface of the substrate layer.

According to some embodiments, a display device according to the above-described embodiments may include a damping stack covering a display area and including a substrate layer and an adhesive layer. According to some embodiments, shock absorption properties may be achieved on the display area by the damping stack, and a proper peeling force may be achieved on a pad area.

According to some embodiments, the shock absorption and peeling properties may be effectively achieved by utilizing light-transmission properties of the substrate layer and a variable adhesive force of the adhesive layer.

### BRIEF DESCRIPTION OF THE DRAWINGS

FIGS. 1 to 14 illustrate a method of manufacturing a display device according to some embodiments.

FIG. 15 is a schematic cross-sectional view illustrating a display device according to some embodiments.

FIG. 16 is a schematic plan view illustrating a display device according to some embodiments.

FIG. 17 is an exploded perspective view of an electronic device according to some embodiments.

FIG. 18 is a block diagram of an electronic device according to some embodiments.

FIG. 19 is a schematic diagram of electronic devices according to some embodiments.

### DETAILED DESCRIPTION

Hereinafter, aspects of some embodiments of the present invention will be described in more detail with reference to the attached drawings. The same reference numerals can l be used for indicating the same elements in the drawings, and repeated descriptions of the same elements can be omitted. Embodiments disclosed in the attached drawings are examples, and is to be understood to include all modifications, equivalents and substitutes included in the spirit and technical scope of the present invention.

The terms “on”, “connected”, “coupled,” etc., used herein refers to a direct placement/connection/combination, and also refers to a case where another element is interposed two different elements.

The terms such as “first”, “second”, “below”, “lower”, “upper”, “above,” etc., are used in a relative sense to distinguish different elements or positions, and do not specify an absolute position or an absolute order.

In the accompanying drawings, a first direction and a second direction may refer to two directions parallel to a display surface of a display device and perpendicular to each other. For example, the first direction may correspond to an X-direction (a row direction or a width direction) of the display device, and the second direction may correspond to a Y-direction (a column direction or a length direction) of the display device. The third direction may be perpendicular to the first direction and the second direction. The third direction may correspond to a Z-direction (a thickness direction) of the display device.

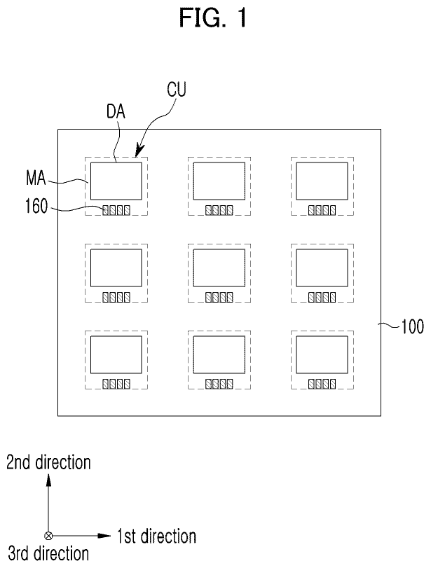

FIGS. 1 to 14 illustrate aspects of a method of manufacturing a display device according to some embodiments.

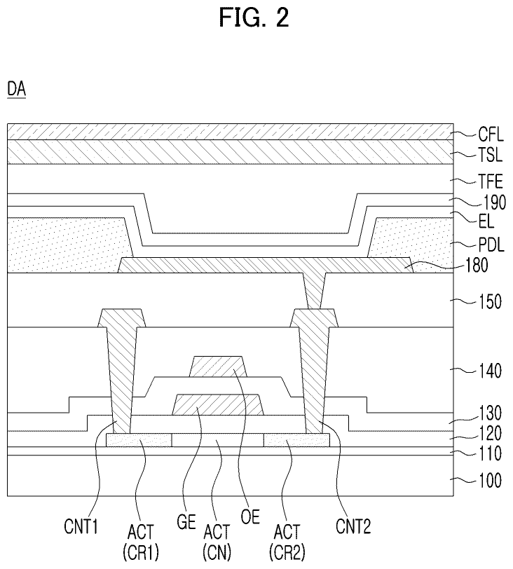

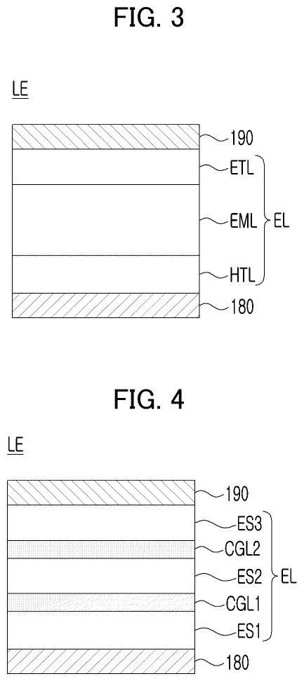

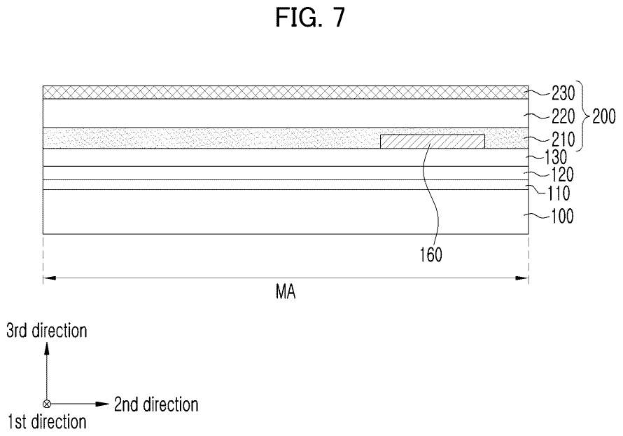

For example, FIGS. 1, 5, 8, 10 and 12 are schematic plan views illustrating the method of manufacturing the display device. FIGS. 2, 6 and 14 are cross-sectional views illustrating a display element formed in a display area and upper layers on the display element. FIGS. 3 and 4 are schematic cross-sectional views illustrating a light-emitting element included in the display element. FIGS. 7, 9, 11 and 13 are schematic cross-sectional views illustrating the method of manufacturing the display device.

Referring to FIG. 1, a plurality of cell units CU may be formed on the base substrate 100 to prepare an original display panel film for forming an individual display device. The cell unit CU may refer to a unit area cut into the individual display device or an individual display panel.

For example, a plurality of the cell units CU may be repeatedly formed along the first direction to define cell unit rows. A plurality of cell unit rows may be repeatedly formed along the second direction.

The cell unit CU may include a display area DA in which a display element may be formed, and a margin area MA surrounding the display area DA. Pads 160 may be formed at one end portion of the margin area MA. According to some embodiments, the pads 160 may be pads for a lighting inspection of the display element.

Referring to FIG. 2, as described above, the display element may be formed in the display area DA. The display element may include a transistor and a light-emitting element electrically connected to the transistor.

The transistor may form a thin film transistor (TFT) array in the display area DA of the base substrate 100.

The base substrate 100 may be provided as a support substrate or a back-plane substrate of a display device. A glass substrate or a plastic substrate may be used as the base substrate 100.

According to some embodiments, the base substrate 100 may include a polymer material having transparency and flexibility. In this case, the base substrate 100 may be used in a transparent flexible display device. For example, the base substrate 100 may include a polymer material such as polyimide, polysiloxane, an epoxy resin, an acrylic resin, polyester, or the like. According to some embodiments, the base substrate 100 may include polyimide.

A buffer layer 110 may be formed on a top surface of the base substrate 100. Moisture or contaminants penetrating through the base substrate 100 may be blocked by the buffer layer 110, and diffusion of impurities or contaminants between the base substrate 100 and structures formed on the base substrate 100 may also be blocked by the buffer layer 110.

The buffer layer 110 may be entirely formed over the display area DA and the margin area MA of the cell unit CU, and may entirely cover the top surface of the base substrate 100.

The buffer layer 110 may include, e.g., an inorganic insulating material such as silicon oxide, silicon nitride or silicon oxynitride. These may be used alone or in a combination thereof. According to some embodiments, the buffer layer 110 may have a stacked structure including a silicon oxide layer and a silicon nitride layer. The buffer layer 110 may be formed by a deposition process such as a chemical vapor deposition (CVD) process, a sputtering process, an atomic layer deposition (ALD) process, or the like, to include the above-mentioned inorganic insulating material.

The active layer ACT may be located on the buffer layer 110 and may be patterned by, e.g., a photo-lithography process so that each pixel may be repeatedly/regularly arranged. The active layer ACT may include a silicon compound such as polysilicon. A p-type dopant or an n-type dopant may be doped in a partial region of the active layer ACT, so that the active layer ACT may include a source region, a drain region, and a channel region.

The active layer ACT may include an oxide semiconductor such as indium gallium zinc oxide (IGZO), zinc tin oxide (ZTO), or indium tin zinc oxide (ITZO).

The gate insulation layer 120 may be formed on the active layer 110, and a gate electrode GE may be stacked on the gate insulation layer 120. The gate insulation layer 120 may extend continuously over a plurality of pixels, and may be included as a common layer for a plurality of the transistors.

According to some embodiments, the gate insulation layer 120 may partially cover each active layer 110, and may be formed in a pattern shape independently formed in each transistor.

The gate electrode GE may overlap the channel region of the active layer ACT in the third direction (thickness direction). A scan signal may be transmitted from the scan line through the gate electrode GE.

The gate insulation layer 120 may be formed by the deposition process to include an inorganic insulating material such as silicon oxide, silicon nitride, silicon oxynitride, a metal oxide, or the like.

According to some embodiments, a p-type dopant or an n-type dopant may be injected into the active layer ACT through an ion implantation process using the gate electrode GE as an ion implantation mask. Accordingly, a first contact region CR1 and a second contact region CR2 may be formed at one side and the other side of the active layer ACT, respectively. The first contact region CR1 and the second contact region CR2 may correspond to a source region and a drain region, respectively.

A portion of the active layer ACT between the first contact region CR1 and the second contact region CR2 which may overlap the gate electrode GE in the third direction (the thickness direction) may be defined as a channel region CN.

The transistor may be defined by the active layer ACT including the first contact region CR1 and the second contact region CR2, the gate insulation layer 120, and the gate electrode GE. The transistor may be formed as a thin film transistor (TFT) of the display device, and may serve as a pixel driving transistor or a switching transistor.

According to some embodiments, the gate insulation layer 120 may be formed in a pattern shape covering the channel region by an etching process using the gate electrode GE as an etching mask. When the active layer ACT includes the oxide semiconductor, hydrogen (H) included in a first insulating interlayer 130 may be diffused or transferred to the active layer ACT when forming the first insulating interlayer 130. Accordingly, a carrier concentration of hydrogen may be relatively increased, and thus the contact regions CR1 and CR2 may be formed at side portions of the active layer ACT.

The first insulating interlayer 130 covering the gate insulation layer 120 and the gate electrode GE may be formed on the active layer ACT. The first insulating interlayer 130 may be formed by the above-described deposition process to include an inorganic insulating material such as silicon oxide, silicon nitride, silicon oxynitride, or the like. The insulating interlayer 130 may be formed in a single-layered structure or a multi-layered structure including different materials.

An overlapping electrode OE may be formed on the first insulating interlayer 130. The overlapping electrode OE may overlap the gate electrode GE in the thickness direction. According to some embodiments, the overlapping electrode OE may serve as an upper gate. According to some embodiments, a storage capacitor may be defined by the gate electrode GE, the first insulating interlayer 130 and the overlapping electrode OE.

A second insulating interlayer 140 covering the overlapping electrode OE may be formed on the first insulating interlayer 130.

According to some embodiments, the overlapping electrode OE may be omitted. In this case, the first and second insulating interlayers 130 and 140 may be formed as a single insulating layer (or substantially a single insulating interlayer).

Contact electrodes CNT1 and CNT2 which may be in contact with or electrically connected to the active layer ACT may be formed on the second insulating interlayer 140.

The contact electrode may include a first contact electrode CNT1 connected to or in contact with the first contact region CR1 of the active layer ACT, and a second contact electrode CNT2 connected to or in contact with the second contact region CR2 of the active layer ACT. The first contact electrode CNT1 and the second contact electrode CNT2 may be provided as a source electrode and a drain electrode, respectively.

According to some embodiments, contact holes may be formed by partially etching the insulating interlayers 130 and 140. For example, contact holes exposing the first contact region CR1 and the second contact region CR2, respectively, may be formed. A metal layer filling the contact holes may be formed on the second insulating interlayer 140 by a deposition process such as a sputtering process, and then the metal layer may be partially etched to form the first contact electrode CNT1 and the second contact electrode CNT2. For example, a data signal may be transferred from the data line through a first contact electrode CNT1.

The gate electrode GE, the overlapping electrode OE, and the contact electrodes CNT1 and CNT2 may include a metal such as Ag, Mg, Al, W, Cu, Ni, Cr, Mo, Ti, Pt, Ta, Nd, Sc, etc., an alloy thereof, or a nitride thereof. The gate electrode GE, the overlapping electrode OE, and the contact electrodes CNT1 and CNT2 may be formed by a deposition process such as a sputtering process and a photo-lithography process.

The gate electrode GE, the overlapping electrode OE, and the contact electrodes CNT1 and CNT2 may be formed in a multi-layered structure (e.g., a Ti layer, an Al layer, and a Ti layer).

A via insulation layer 150 covering the contact electrodes CNT1 and CNT2 may be formed on the second insulating interlayer 140. The via insulation layer 150 may be provided as a planarization layer of the thin film transistor (TFT)-array.

The via insulation layer 150 may be partially etched to form a via hole exposing a top surface of a contact electrode (e.g., the second contact electrode CNT2). An electrode layer filling the via hole may be formed on the top surface of the via insulation layer 150, and then the electrode layer may be partially etched to form a pixel electrode 180. The pixel electrode 180 may interact with the transistor through the second contact electrode CNT2.

The via insulation layer 150 may be formed as an organic insulation layer. For example, the via insulation layer 150 may include an organic polymer material such as polyimide, an epoxy resin, an acrylic resin, polyester, a siloxane resin, benzocyclobutene (BCB), or the like. For example, the via insulation layer 150 may be formed by a coating process such as a spin coating process.

The pixel electrode 180 may serve as an anode, and may include a high work function conductive material to promote hole injection. The pixel electrode 180 may be formed as a transmissive electrode. The pixel electrode 180 may be formed to include a transparent conductive oxide such as indium tin oxide (ITO), indium zinc oxide (IZO), zinc oxide (ZnO), indium tin oxide (ITZO), or the like.

The pixel electrode 180 may be formed as a translucent electrode or a reflective electrode. In some configurations, the pixel electrode 180 may be formed as a reflective electrode. The pixel electrode 180 may include a metal selected from Ag, Mg, Cu, Al, Pt, Pd, Au, Ni, Nd, Ir, Cr, Li, Ca, LiF, Mo, Ti, W, In, Sn or Zn, or an alloy or a compound (e.g., LiF) including at least one of the metals.

The pixel electrode 180 may have a single-layered structure or a multi-layered structure. According to some embodiments, the pixel electrode 180 may have a triple-layered structure of, e.g., ITO/Ag/ITO or ITO/Al/ITO.

A pixel defining layer PDL may be formed on the via insulation layer 150 to at least partially expose a top surface of the pixel electrode 180. The pixel defining layer PDL may cover a peripheral portion of the pixel electrode 180.

A pixel region or a light-emitting region may be defined by a sidewall of the pixel defining layer PDL. For example, a green emission region, a blue emission region, and a red emission region may be separated and defined by the pixel defining layer PDL.

The pixel defining layer PDL may include an organic material such as a polysiloxane resin, a polyimide resin, an acrylic resin, or the like. The pixel defining layer PDL may include a colorant such as a black pigment/dye dispersed in a resin material.

According to some embodiments, the pixel defining layer PDL may have a repeatedly stacked (e.g., alternating, or repeatedly alternating) structure of a silicon oxide layer and a silicon nitride layer.

A light-emitting portion EL may be formed on the pixel electrode 180 and the pixel defining layer PDL. The light-emitting portion EL may include an organic emission layer that may be independently patterned for each of a red pixel, a green pixel, and a blue pixel to generate light of different colors for each of the pixels.

According to some embodiments, the light-emitting portion EL may continuously and commonly extend across a plurality of the pixels. In this case, the light-emitting portion EL may include a white emission layer. According to some embodiments, the light-emitting portion EL may include emission layers corresponding to a plurality of different colors or the same color, and may have a tandem-stacked structure.

For example, the light-emitting portion EL may be formed by a process such as a thermal deposition, a vapor deposition, a vacuum deposition, a spin coating, an inkjet printing, a laser printing, a casting, a laser thermal transfer, or the like.

Constructions of the light-emitting element including the light-emitting portion EL will be described in more detail with reference to FIGS. 3 and 4.

A counter electrode 190 may be formed on the light-emitting portion EL. The counter electrode 190 may be a common electrode continuously provided in a plurality of the light-emitting regions or the pixels.

The counter electrode 190 may serve as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. These may be used alone or in a combination thereof.

The counter electrode 190 may be formed as a transmissive electrode, a translucent electrode, or a reflective electrode. The counter electrode 190 may have a single-layered structure or a multi-layered structure.

The light-emitting element may be defined by the pixel electrode 180, the light emitting portion EL, and the counter electrode 190. The light-emitting element may be provided as an organic light-emitting diode (OLED) element.

An encapsulation layer TFE may be formed on the counter electrode 190. The encapsulation layer TFE may be located on the pixel defining layer PDL and the light-emitting elements to protect the light-emitting elements from external contaminants such as moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, acrylic resin (e.g., polymethylmethacrylate, polyacrylic acid, etc.), an epoxy resin (e.g., aliphatic glycidyl ether (AGE)), or any combination thereof; or a combination of inorganic and organic layers.

The encapsulation layer TFE may be formed in a single-layered or a multi-layered structure. According to some embodiments, the encapsulation layer TFE may have a sequential stacked structure of a first inorganic layer, an organic layer, and a second inorganic layer.

A touch sensor layer TSL and/or a color filter layer CFL may be stacked on the encapsulation layer TFE. The touch sensor layer TSL may include a sensing electrode layer and a sensor substrate layer. The sensing electrode layer may include electrode layers having a multi-layered structure with a sensor insulating interlayer interposed therebetween.

The color filter layer CFL may include a color pattern including a blue color filter layer, a red color filter layer, and a green color filter layer. The color filter layer CFL may further include a filter substrate on which the blue color filter layer, the red color filter layer, and the green color filter layer are formed, and may further include a bank that may divide the blue color filter layer, the red color filter layer, and the green color filter layer.

According to some embodiments, the display element may have a pol-less structure that does not include a polarizing plate. For example, the color filter layer CFL may be included in the display element in the form of an on-cell film OCF, and may replace the polarizing plate. According to some embodiments, the color filter layer CFL may further include a light scattering layer formed between the filter substrate and the color pattern, and may effectively suppress and relatively reduce reflection of external light.

Referring to FIG. 3, the light-emitting element LE may include the pixel electrode 180, the counter electrode 190, and the light-emitting portion EL located between the pixel electrode 180 and the counter electrode 190 as described above.

The light-emitting portion EL may include a hole transport layer HTL, an emission layer EML and an electron transport layer ETL. According to some embodiments, the hole transport layer HTL, the light emitting layer EML, the electron transport layer ETL, and the counter electrode 190 may be sequentially stacked from a top surface of the pixel electrode 180.

The emission layer EML may include an organic light-emitting material having red, green or blue emission properties. For example, the emission layer EML may include a fluorescent host and/or a host for a phosphorescent device, and may further include a fluorescent dopant, a phosphorescent dopant, and/or a thermally activated delayed fluorescence (TADF) dopant.

For example, the hole transport layer HTL may include a hole transport material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N, N′-di(naphthalene-l-yl)-N, N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport layer ETL may include an electron transport material such as Alq₃ (tris(8-hydroxyquinolinato)aluminum), TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

According to some embodiments, a hole injection layer may be further located between the pixel electrode 180 and the hole transport layer HTL. An electron injection layer may be further located between the counter electrode 190 and the electron transport layer ETL.

According to some embodiments, the hole transport layer HTL and the electron transport layer ETL may each be formed as a common layer continuously extending across a plurality of the pixels. The emission layer EML may be independently patterned for individual pixels of different colors.

Referring to FIG. 4, the light-emitting portion EL may include a plurality of light-emitting structures ES1, ES2 and ES3. Each of the light-emitting structures ES1, ES2 and ES3 may include an emission layer, and may further include a hole transport layer and an electron transport layer. According to some embodiments, the light-emitting element of FIG. 4 may have a tandem structure that may generate a white light or a blue light.

Charge generation layers CGL1 and CGL2 may be located between neighboring light-emitting structures ES1, ES2 and ES3. The charge generation layers CGL1 and CGL2 may include a p-type charge generation layer and/or an n-type charge generation layer. The charge generation layers CGL1 and CGL2 may include a first charge generation layer CGL1 located between a first light-emitting structure ES1 and a second light-emitting structure ES2, and a second charge generation layer CGL2 located between the second light-emitting structure ES2 and a third light-emitting structure ES3.

According to some embodiments, the first light-emitting structure ES1, the first charge generation layer CGL1, the second light-emitting structure ES2, the second charge generation layer CGL2, the third light-emitting structure ES3, and the second electrode 190 may be sequentially stacked from the top surface of the pixel electrode 180.

The light-emitting portion EL included in the light-emitting element may be provided as a common layer for a plurality of the pixels. According to some embodiments, a blue light or a white light may be emitted from the light-emitting portion EL, and a color for each pixel may be implemented by the above-described color filter layer CFL.

FIG. 4 illustrates an example of the light-emitting element having a triple-layered tandem structure, but the light-emitting element may have a double-layered tandem structure or a tandem structure having four or more layers.

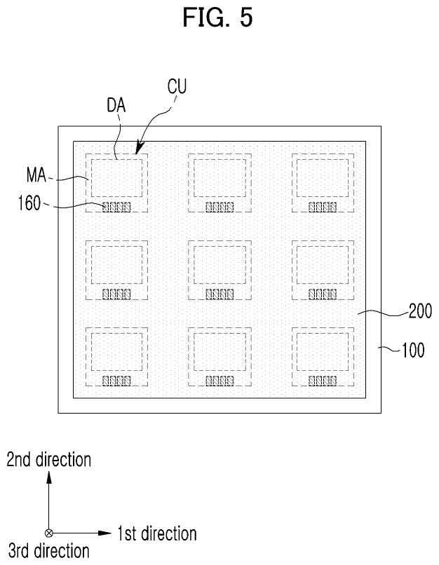

Referring to FIGS. 5 to 7, a damping stack 200 that may commonly cover a plurality of the cell units CU may be formed on the top surface of the base substrate 100. According to some embodiments, a lower protective film may be attached to a bottom surface of the base substrate 100.

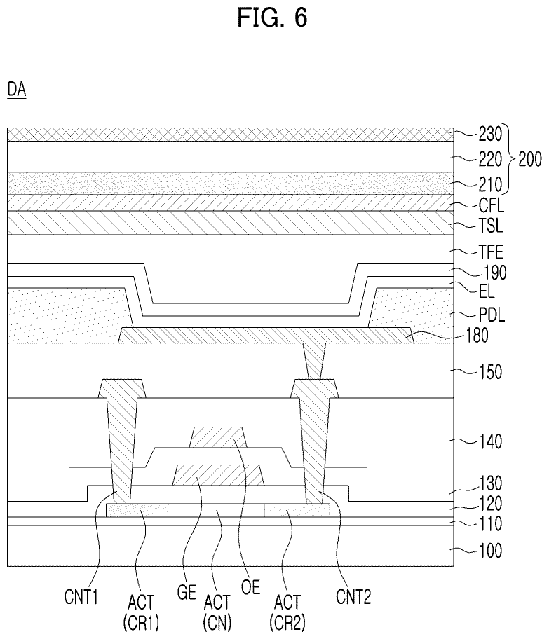

As illustrated in FIG. 6, the damping stack 200 may be attached onto the display element in the display area DA. For example, the damping stack 200 may be attached onto the color filter layer CFL or the touch sensor layer TSL.

As illustrated in FIG. 7, the damping stack 200 may be continuously formed on the margin area MA to cover the pads 160. Although FIG. 7 illustrates that the pads 160 are located on the first insulating interlayer 130, the pads 160 may be located on the second insulating interlayer 140. For example, the via insulation layer 150 may not be formed on the margin area MA or may be removed on the margin area MA.

According to some embodiments of the present invention, the damping stack 200 may include a substrate layer 220 and an adhesive layer 210 formed on one surface of the base layer 220. According to some embodiments, a protective layer 230 may be formed on the other surface of the substrate layer 220. The damping stack 200 may be attached onto the cell unit CU or the display element by the adhesive layer 210.

The adhesive layer 210 may include an acrylic resin, a silicone resin, a urethane resin, and/or a rubber-based adhesive material. For example, the adhesive layer 210 may include a pressure sensitive adhesive (PSA).

The substrate layer 220 may include a polymer material having a modulus or an elastic modulus higher than that of the adhesive layer 210. For example, the substrate layer 220 may include a polymer film including a cyclic olefin polymer (COP), polyethylene terephthalate (PET), polyacrylate (PAR), polyetherimide (PEI), polyethylene naphthalate (PEN), polyphenylene sulfide (PPS), polyallylate, polyimide (PI), polyurethane (PU), cellulose acetate propionate (CAP), polyether sulfone (PES), cellulose triacetate (TAC), polycarbonate (PC), cyclic olefin copolymer (COC), polymethyl methacrylate (PMMA), or the like.

According to some embodiments, the substrate layer 220 may include cellulose triacetate (TAC). In this case, ultraviolet (UV) cut performance may be relatively improved to enhance stability of the display element.

According to some embodiments, the protective layer 230 may be a temporary protective film having a release property. According to some embodiments, the protective layer 230 may be a layer permanently remaining in the damping stack 200 or the display device such as a hard coating layer.

According to some embodiments of the present disclosure, the substrate layer 220 may have a transmittance of 20% or less for a light having a wavelength of 380 nm or less. When the transmittance of the base layer 220 for the light having a wavelength of 380 nm or less exceeds 20%, UV stability of the display element may be deteriorated. For example, as the organic layer included in the display device is continuously exposed to UV introduced from an outside, defects such as outgassing may occur.

According to some embodiments, the transmittance of the substrate layer 220 for the light having a wavelength of 380 nm or less may be 15% or less, 10% or less, 8% or less, 7% or less, 6% or less, or 5% or less. According to some embodiments, a transmittance of the substrate layer 220 for a light having a wavelength of 370 nm or less may be 5% or less, 3% or less, 2% or 1% or less, or 0.5% or less. In the above range, UV stability of the display element may be more effectively achieved.

According to some embodiments of the present disclosure, a transmittance of the substrate layer 220 for a light having a wavelength of 390 nm or more may be 10% or more. When the transmittance of the substrate layer 220 for the light having a wavelength of 390 nm or more is less than 10%, sufficient curing of the adhesive layer 210 on the display area DA may not be implemented.

According to some embodiments, the transmittance of the substrate layer 220 to the light having a wavelength of 390 nm or more may be 20% or more, 30% or more, or 40% or more. According to some embodiments, the transmittance of the substrate layer 220 to a light having a wavelength of 400 nm or more may be 50% or more, or 60% or more. In the above range, curing of the adhesive layer 210 may be further promoted to further relatively improve stability of the display element in a subsequent process (e.g., a module process).

According to some embodiments, a transmittance of the substrate layer 220 for a light having a wavelength ranging from 9 micrometers (μm) to 11 μm may be 10% or less. In the above range, damages to the display element or the light-emitting element by, e.g., a CO2 laser in a cutting process using the CO2 laser may be suppressed. According to some embodiments, the transmittance of the substrate layer 220 for the light having a wavelength ranging from 9 μm to 11 μm may be less than 10%, 9% or less, 8% or less, or 5% or less.

An adhesive force (e.g., an adhesive force before curing) of the adhesive layer 210 may be 70 grams-force per inch (gf/in) or less. According to some embodiments, the adhesive force of the adhesive layer 210 may be in a range from 10 gf/in to 70 gf/in, from 20 gf/in to 70 gf/in, from 10 gf/in to 60 gf/in, from 20 gf/in to 60 gf/in, from 10 gf/in to 50 gf/in, or from 20 gf/in to 50 gf/in.

In the adhesive force range, a partial cutting of the damping stack may be easily performed as will be described later while maintaining the adhesion of the damping stack 200.

The adhesive force of the adhesive layer 210 may be measured by attaching the damping stack 200 to a glass, leaving the damping stack 200 at a temperature of 25° C. for 24 hours, and then peeling at 180° at a speed of 300 mm per minute.

According to some embodiments, an adhesive force (the adhesive force before curing) of the substrate layer 220 to the adhesive layer 210 may be less than an adhesive force (the adhesive force before curing) of the protective layer 230 to the substrate layer 220.

According to some embodiments, the adhesive force (the adhesive force before curing) of the substrate layer 220 to the adhesive layer 210 may be in a range from 3 gf/in to 10 gf/in, from 4 gf/in to 9 gf/in, or from 5 gf/in to 9 gf/in.

According to some embodiments, the adhesive force (the adhesive force before curing) of the protective layer 230 to the substrate layer 220 may be in a range from 10 gf/in to 15 gf/in, from 10 gf/in to 14 gf/in, or from 11 gf/in to 14 gf/in.

According to some embodiments, a thickness of the substrate layer 220 may be greater than a thickness of the adhesive layer 210. Accordingly, sufficient shock absorption or damping properties through the substrate layer 220 may be implemented.

According to some embodiments, the thickness of the substrate layer 220 may be in a range from 20 μm to 50 μm, from 20 μm to 40 μm, or from 25 μm to 40 μm. The thickness of the adhesive layer 210 may be in a range from 10 μm to 25 μm, or from 10 μm to 20 μm.

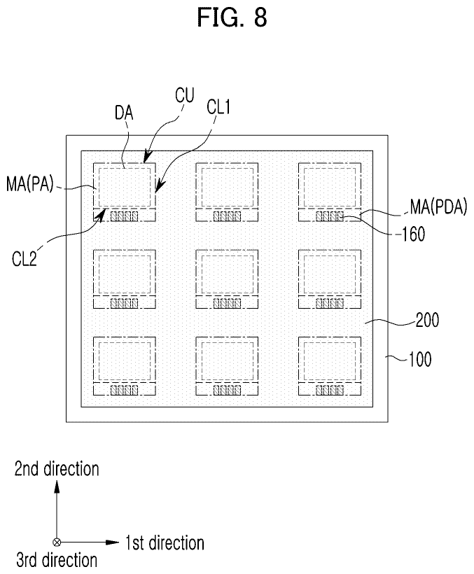

Referring to FIG. 8, a first cutting line CL1 for cutting each cell unit CU may be set, and a second cutting line CL2 for a partial cutting of the pad area (PDA) may be set on a top surface (e.g., a top surface of the protective layer 230) of the damping stack 200.

The first cutting line CL1 may be a full-cutting line for separation of each of the cell units CU. The second cutting line CL2 may be a partial-cutting line or a half-cutting line for partial removal of the damping stack in the pad area PDA as described below.

The margin area MA may be divided into a peripheral area PA and a pad area PDA by the second cutting line CL2. The peripheral area PA may surround the display area DA, and the pad area PDA may be spaced apart from the display area DA with the peripheral area PA interposed therebetween.

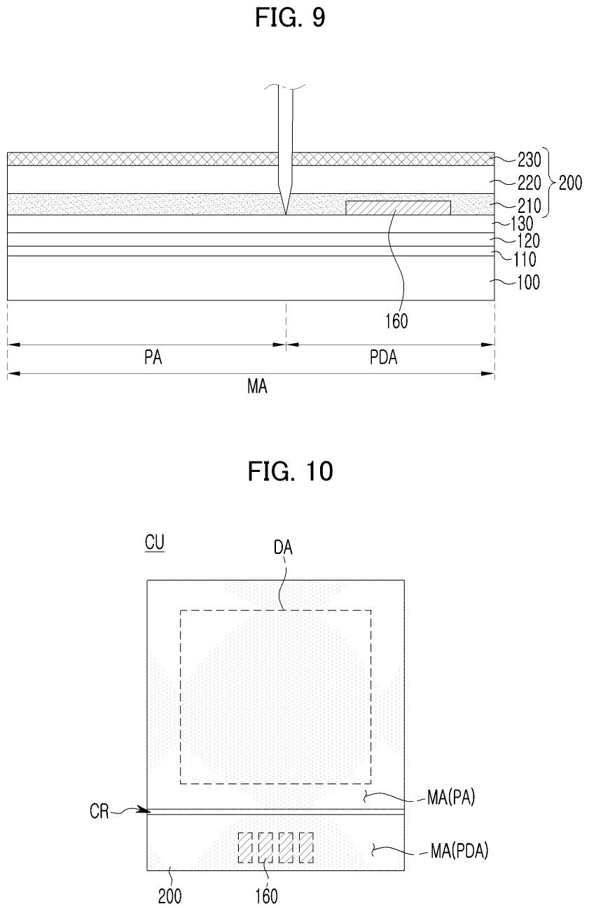

Referring to FIGS. 9 and 10, the cell unit CU may be separated along the first cutting line CL1 through a full-cutting. Only the damping stack 200 may be partially-cut or half-cut along the second cutting line CL2 to form a partial cutting region CR.

According to some embodiments, the cutting process by the first cutting line CL1 and the second cutting line CL2 may be performed using a CO2 laser beam or a yttrium aluminum garnet (YAG) laser beam. According to some embodiments, the cutting process may be performed using the CO2 laser beam.

As illustrated in FIG. 9, the cutting process by the second cutting line CL2 may be performed to cut only the damping stack 200 by adjusting an irradiation time and/or an intensity of the laser beam. Accordingly, the partial cutting region CR may be formed to distinguish the peripheral area PA from the pad area PDA.

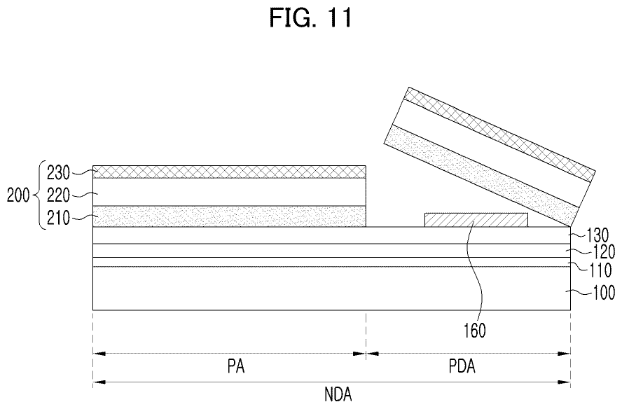

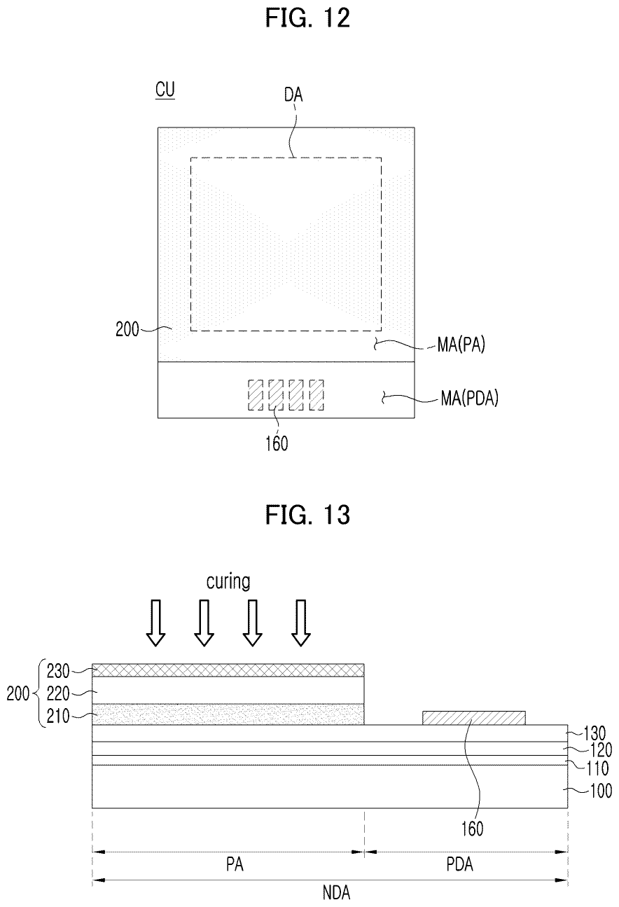

Referring to FIGS. 11 and 12, a portion of the damping stack 200 formed in the pad area PDA may be peeled-off or removed using the partial cutting region CR. Accordingly, the damping stack 200 may remain on the display area DA and the peripheral area PA, and the pads 160 may be exposed on the pad area PDA.

As described above, the adhesive force (the adhesive force before curing) with respect to the adhesive layer 210 of the substrate layer 220 may be less than the adhesive force (the adhesive force before curing) with respect to the substrate layer 220 of the protective layer 230. Accordingly, during the partial peeling process, the protective layer 230 may be removed together without being separated from the substrate layer 220.

Referring to FIG. 13, the damping stack 200 remaining in the display area DA and the peripheral area PA may be cured. Accordingly, the adhesive force of the adhesive layer 210 may be increased.

According to some embodiments, the curing process may be performed using an ultraviolet (UV) ray having a wavelength 390 nm or more. As described above, the transmittance of the substrate layer 220 to the light having a wavelength of 390 nm or more may be 10% or more. Accordingly, the adhesive layer 210 may be cured using the light having a wavelength 390 nm or more while blocking (or substantially blocking) a light having a wavelength 380 nm or less through the substrate layer 220.

According to some embodiments, the curing process may be performed using a light having a wavelength in a range from 390 nm to 480 nm, from 390 nm to 450 nm, from 390 nm to 430 nm, or from 390 nm to 410 nm.

The curing process may be performed such that the adhesive force (an adhesive force after curing) of the adhesive layer 210 may be increased to 250 gf/in or more, or 300 gf/in or more. According to some embodiments, the adhesive layer may include a binder resin such as an acrylic resin, a photo-polymerizable compound including an acrylate group, and a photo-initiator. The photo-initiator may include a compound having an activity for the light having a wavelength of 390 nm or more.

For example, radicals may be generated by the light with a wavelength of 390 nm or more from the photo-initiator, and a crosslinking reaction of the photo-polymerizable compound and/or the binder resin may be induced by the generated radicals.

Accordingly, the damping stack 200 may be stably fixed on the cell unit CU to provide the damping properties of the display element or the display device. Additionally, the subsequent module process may be stably performed.

According to some embodiments, the adhesive force of the adhesive layer 210 after the curing may be in a range from 250 gf/in to 500 gf/in, from 300 gf/in to 500 gf/in, from 300 gf/in to 450 gf/in, from 300 gf/in to 400 gf/in.

An adhesive strength between the substrate layer 220 and the adhesive layer 210 may also be increased by the curing process. Accordingly, the substrate layer 220 may be stably fixed on the adhesive layer 210 to provide the shock absorption and damping properties.

According to some embodiments, the adhesive force between the substrate layer 220 and the adhesive layer 210 after curing may be 300 grams-force per inch (gf/in) or more, from 300 gf/in to 500 gf/in, from 300 gf/in to 450 gf/in, or 300 gf/in to 400 gf/in.

According to some embodiments, after curing the above-described damping stack 200, a lighting test of the light-emitting element LE included in the display element may be performed through the pads 160 exposed by the partial filling of the damping stack 200. After the lighting test, the pad area PDA including the pads 160 may be at least partially cut to remove the pads 160.

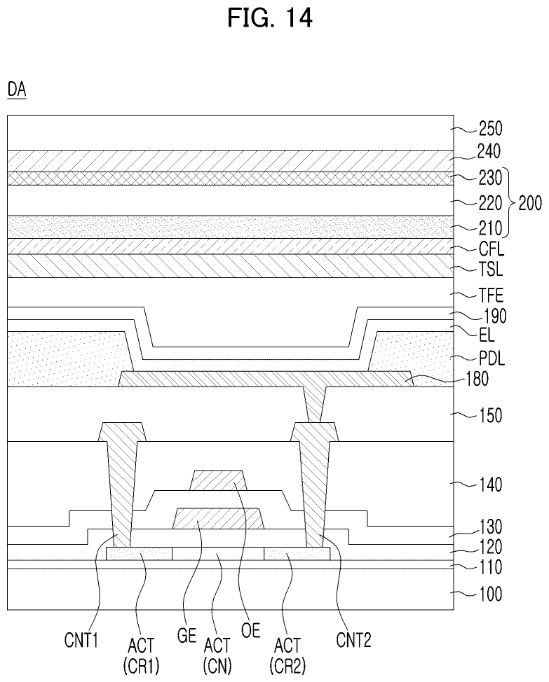

Referring to FIG. 14, an outer film 250 may be stacked on the damping stack 200. For example, an OCR-based upper adhesive layer 240 may be stacked on the damping stack 200. The outer film 250 may be attached to the damping stack 200 through the upper adhesive layer 240.

According to some embodiments, the outer film 250 may be provided as a window film of a display device. The outer film 250 may include a functional layer such as an anti-static layer, an anti-reflection layer, a hard coating layer, or the like.

According to some embodiments, the upper adhesive layer 240 may be formed on the substrate layer 220 after peeling the protective layer 230 included in the damping stack 200. According to some embodiments, as illustrated in FIG. 14, the upper adhesive layer 240 may be formed on the protective layer 230 in a state that the protective layer 230 is present.

According to some embodiments, an additional outer cutting process for a circumferential portion of the cell unit CU may be further performed. According to some embodiments, the outer cutting process may be performed after the above-described cutting process of the pad area PDA.

Thereafter, the module process that may include combination of a support structure and connection of the printed circuit board to a bottom surface of the base substrate 100 may be performed.

According to the above-described embodiments, as illustrated in FIG. 14, the display device may not include a polarizing plate. Accordingly, a thickness of the display device may be relatively reduced, and flexible, bendable and/or foldable properties may be relatively enhanced. According to some embodiments of the present disclosure, the damping stack 200 may be included to buffer or suppress degradation in UV-cutting and shock absorption performance due to omission of the polarizing plate.

As described above, the damping stack 200 may function as a protective film during the cutting process and may remain on the display device or the display element. Thus, a process of removing the protective film in the form of a release film may be omitted, and the damping stack 200 may exist as an upper shock absorbing structure or an upper shock alleviating structure in a product of the display device or the display element.

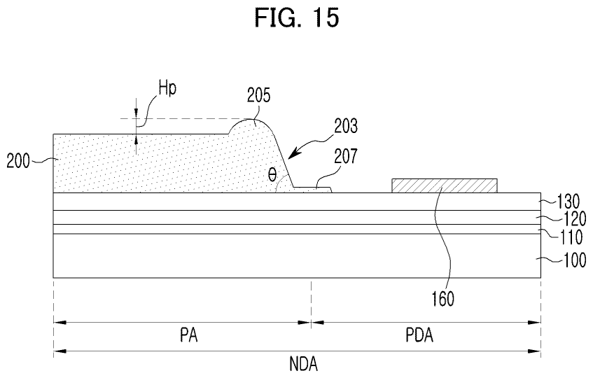

FIG. 15 is a schematic cross-sectional view illustrating a display device according to some embodiments. For convenience of illustration and description, detailed illustration of the adhesive layer 210, the substrate layer 220, and the protective layer 230 are omitted in FIG. 15.

Referring to FIG. 15, an end portion of the damping stack remaining after the partial peeling of the damping stack 200 may include an inclined surface 203.

An inclination angle (e.g., an inclination angle with respect to the top surface of the base substrate 100) of the inclination surface 203 may be in a range from 50° to 80°, from 60° to 80°, or from 70° to 80°. The inclination angle of the inclined surface 203 may be adjusted to the above-described range, lifting or peel-off of the damping stack 200 formed in the peripheral area PA or the display area DA may be prevented or reduced in the partial peeling process.

According to some embodiments, an end portion of the damping stack 200 may include a tail portion 207. The tail portion 207 may extend from an end portion of the damping stack 200 on the margin area MA. According to some embodiments, the tail portion 207 exists in a boundary area between the peripheral area PA and the pad area PDA, and may partially extend onto the pad area PDA.

The adhesion of the damping stack 200 on the display area DA and the peripheral area PA may be more stably maintained by the tail portion 207. Additionally, bending or folding stability in the peripheral area PA may be relatively improved by the tail portion 207.

For example, the thickness of the tail portion 207 may be 1/10 or less, 1/20 or less, 1/30 or less, 1/40 or less, or 1/50 or less of the thickness of the damping stack 200. For example, the thickness of the tether 207 may be 1/200 or more, or 1/100 or more of the thickness of the damping stack 200.

According to some embodiments, the end portion of the damping stack 200 may include a protrusion 205. The protrusion 205 may protrude from the end portion of the damping stack 200 in a thickness direction (the third direction).

A bending stress or a folding stress applied to the damping stack 200 may be buffered or absorbed by the protrusion 205 at the end portion. According to some embodiments, a height Hp of the protrusion 205 may be adjusted in a range from 5 μm to 30 μm, from 5 μm to 20 μm, from 5 μm to 15 μm, or from 5 μm to 10 μm in consideration of the stress alleviation and additional stacking processes.

As illustrated in FIG. 15, a height Hp of the protrusion 205 may be a vertical distance between a top surface of the damping stack 200 excluding the protrusion 205 and a peak point of the protrusion 205 in the third direction (the thickness direction).

The height Hp, the inclination angle θ, and a length of the tail portion 207 of the protrusion 205 may be adjusted by controlling a spot size, an irradiation energy, an irradiation time, or the like, of the laser beam in the above-described partial peeling process.

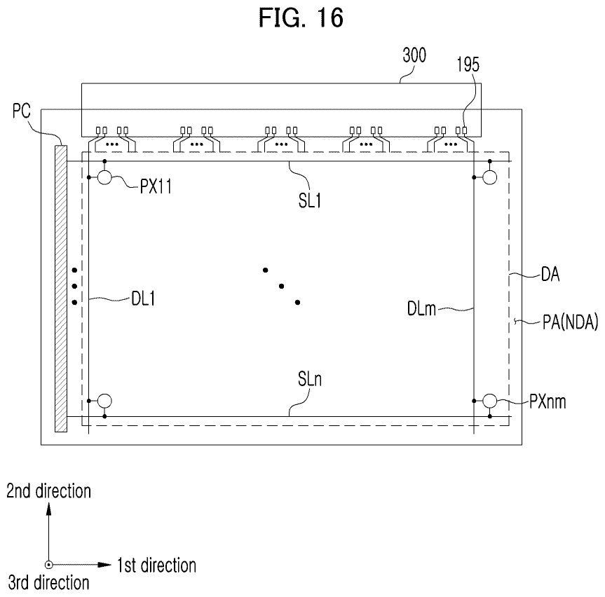

FIG. 16 is a schematic plan view illustrating a display device according to some embodiments.

Referring to FIG. 16, a pixel circuit including scan lines (or gate lines) SL1 to SLn forming first to n^{th} rows and data lines DL1 to DLm forming first to m^{th} columns may be arranged on the base substrate 100 of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a pixel driving/switching element including the transistor and the light-emitting element as described above. According to some embodiments, the pixel circuit may further include wirings such as a power line, a ground line, etc.

FIG. 16 illustrates that the data lines DL1 to DLm extend in the second direction and the scan lines SL1 to SLn extend in the first direction, but the construction of the data lines and the scan lines is not limited to that illustrated in FIG. 16.

The peripheral area PA may include a non-display area NDA. A peripheral circuit PC may be located in the non-display area NDA. For example, the peripheral circuit PC may include a gate driving circuit. The gate driving circuit may be integrated into the display device by an oxide semiconductor gate (OSG) driver circuit process, an amorphous silicon gate (ASG) driver circuit process, a polysilicon gate (PSG) driver circuit process.

The peripheral circuit PC may further include a data driver, a gate driver, a light-emitting driver, a power voltage generator, a timing controller, or the like.

The display device may further include a printed circuit board 300. Driving pads 195 of the pixel circuit may be assembled at one end portion of the non-display area NDA. The printed circuit board 300 may be electrically connected to the pixel circuit through the driving pads 195. For example, the printed circuit board 300 may be electrically connected to the driving pads 195 by a heating-compression process using a conductive intermediate structure such as an anisotropic conductive film ACF.

An integrated circuit (IC) such as a data driving circuit may be located on the printed circuit board 300. According to some embodiments, an integrated circuit (IC) chip in the form of a chip-on-film (COF) may be mounted on the printed circuit board 300.

As described above, the pads 160 corresponding to inspection pads may be removed from the pad area PDA, and the driving pads 195 corresponding to actual pads of the display device may remain in the peripheral area PA to be connected to the printed circuit board 300.

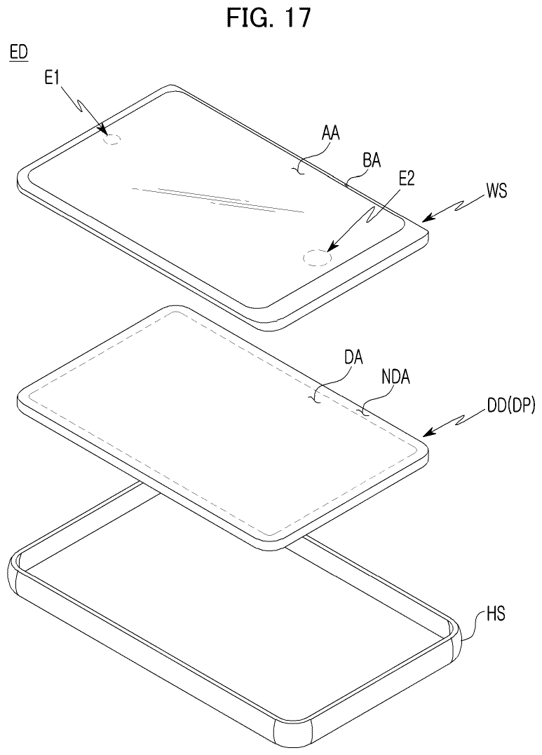

FIG. 17 is an exploded perspective view of an electronic device according to some embodiments.

According to example embodiments, the electronic device may be implemented in the form of a mobile phone (smart phone), a tablet, a PC, or the like, including the above-described display device.

Referring to FIG. 17, the electronic device ED may include a window structure WS, a display device DD, and a housing HS. The display device DD may include a display panel DP including the transistors, the light-emitting elements LE and the damping stack 200 as described above. The housing HS, the display device DD, and the window structure WS may be sequentially stacked along the third direction.

The window structure WS may provide an external display surface recognized by a user, such as a viewing surface of a mobile phone, and may include a transparent material film. For example, the window structure WS may include glass (e.g., ultra-thin glass (UTG)), a hard coating film, a plastic film, or the like.

According to some embodiments, the outer film 250 illustrated in FIG. 14 may be provided as the window structure WS or may be included in the window structure WS.

An outer surface of the window structure WS may include an active area AA and a bezel area PA. The active area AA may provide a surface from which an image of the display device DD is displayed and to which a user's touch/command is input.

The display device DD or the display panel DP may include the display area DA and the non-display area NDA. The display area DA of the display panel DP may correspond to or overlap the active area AA of the window structure WS. The non-display area NDA of the display panel DP may correspond to or overlap the bezel area PA of the window structure WS.

According to some embodiments, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

The housing HS may serve as a frame structure or a rear housing of the display device DD or the electronic device ED. A cover panel may be located between the housing HS and the display panel DP. The housing HS or the cover panel may include a plate (e.g., an SUS plate) that supports the display panel DP. The housing HS or the cover panel may include an elastic body for absorbing shock of the display device DD.

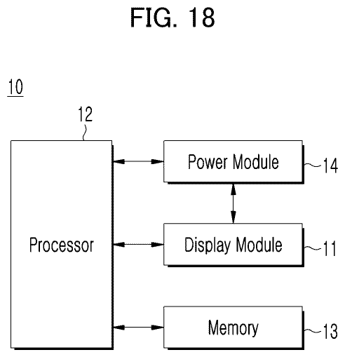

FIG. 18 is a block diagram of an electronic device according to some embodiments.

Referring to FIG. 11, an electronic device 10 according to some embodiments may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

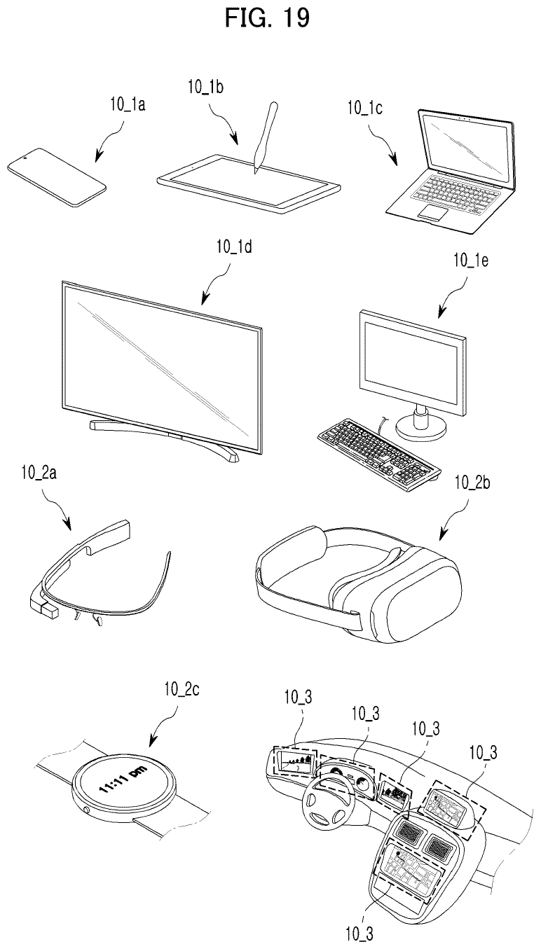

FIG. 19 is a schematic diagram of electronic devices according to some embodiments.

Referring to FIG. 19, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, or the like; a wearable electronic device including a display module such as smart glasses 10_2a, a head mounted display 10_2b, a smart watch 10_2c, or the like; a vehicle electronic device 10_3 including a display module such as a center information display (CID) arranged at or in a vehicle instrument panel, a center fascia, a dashboard, etc., a head-up display, a room mirror display, or the like. The electronic device may include a virtual reality glass or an augmented reality glass.

What is claimed is:

1. A method of manufacturing a display device, comprising:
forming a plurality of cell units including an display element and a pad on a base substrate;
forming a damping stack on the base substrate, wherein the damping stack comprises a substrate layer covering the cell units and having a transmittance of 20% or less for a light having a wavelength of 380 nanometers (nm) or less, and an adhesive layer formed on one surface of the substrate layer;
removing a portion of the damping stack covering the pad; and
curing a remaining portion of the damping stack using a light having a wavelength of 390 nm or more.

2. The method of claim 1, further comprising, after forming the damping stack:
performing a full-cutting for an individual separation of the cell units; and
performing a partial-cutting for partially cutting only the damping stack.

3. The method of claim 2, wherein the full-cutting is performed along a first cutting line extending along a periphery of the cell unit, and the partial-cutting is performed along a second cutting line defining a pad area in which the pad is arranged.

4. The method of claim 3, wherein removing the portion of the damping stack covering the pad comprises peeling a portion of the damping stack formed on the pad area.

5. The method of claim 3, further comprising performing a lighting test through the pad after removing the damping stack or curing the damping stack.

6. The method of claim 5, further comprising removing the pad by at least partially cutting the pad area after performing the lighting test.

7. The method of claim 1, wherein the transmittance of the substrate layer for the light having a wavelength of 380 nm or less is 10% or less.

8. The method of claim 1, wherein a transmittance of the substrate layer for the light having a wavelength of 390 nm or more is 20% or more.

9. The method of claim 1, wherein a transmittance of the substrate layer for a light having a wavelength of 400 nm or more is 50% or more.

10. The method of claim 1, wherein an adhesive force of the adhesive layer before curing is 70 grams-force per inch (gf/in) or less.

11. The method of claim 1, wherein an adhesive force of the adhesive layer after curing is 250 grams-force per inch (gf/in) or more.

12. The method of claim 1, wherein the adhesive force of the adhesive layer after curing is 300 grams-force per inch (gf/in) or more.

13. The method of claim 1, wherein the damping stack further comprises a protective layer formed on the other surface of the substrate layer, and
an adhesive force of the protective layer to the substrate layer before curing is greater than an adhesive force of the substrate layer to the adhesive layer before curing.

14. The method of claim 1, wherein a transmittance of the substrate layer for a light having a wavelength in a range from 9 micrometers (μm) to 11 μm is 10% or less.

15. A display device, comprising:
a base substrate;
a transistor on the base substrate;
a light-emitting element electrically connected to the transistor; and
a damping stack covering the light-emitting element, the damping stack comprises:
a substrate layer having a transmittance of 20% or less for a light having a wavelength of 380 nanometers (nm) or less and a transmittance of 20% or more for a light having a wavelength of 390 nm or more; and
an adhesive layer on one surface of the substrate layer.

16. The display device of claim 15, wherein a transmittance of the substrate layer for the light having a wavelength of 380 nm or less is 10% or less, and a transmittance of the substrate layer for the light having a wavelength of 390 nm or more is 30% or more.

17. The display device of according to claim 15, wherein an end portion of the damping stack has an inclined surface having an inclination angle in a range of 50° to 80° with respect to a top surface of the base substrate.

18. The display device of claim 17, wherein the base substrate has a display area in which the transistor and the light-emitting element are arranged and a margin area around the display area, and
the damping stack includes a tail portion extending from the end portion to the margin area.

19. The display device according to claim 17, wherein the damping stack includes a protrusion formed on an upper portion of the end portion, and a height of the protrusion is in a range from 5 micrometers (μm) to 30 μm from a top surface of the damping stack.

20. An electronic device, comprising:
a display device;
a memory; and
a processor configured to control an operation of the display device by executing data included in the memory, the display device comprising:
a base substrate;
a transistor on the base substrate;
a light-emitting element electrically connected to the transistor; and
a damping stack covering the light-emitting element, the damping stack comprising:
a substrate layer having a transmittance of 20% or less for a light having a wavelength of 380 nanometers (nm) or less and a transmittance of 20% or more for a light having a wavelength of 390 nm or more; and
an adhesive layer on one surface of the substrate layer.
